(19) United States
(12) Patent Application Publication
(10) Pub. No.: US 2026/0048983 A1
(43) Pub. Date: Feb. 19, 2026

(54) METHODS AND SYSTEMS FOR STACKED MICROELECTROMECHANICAL SYSTEM DEVICES

(71) Applicant: MiraMEMS Sensing Technology Co., Ltd, SUZHOU INDUSTRIAL PARK (CN)

(72) Inventors: YU-HAO CHIEN, SUZHOU INDUSTRIAL PARK (CN); Cheng-Lun CHO, SUZHOU INDUSTRIAL PARK (CN)

(21) Appl. No.: 19/301,425

(22) Filed: Aug. 15, 2025

(30) Foreign Application Priority Data
Aug. 15, 2024 (CN) 202411118982.4

(51) Int. Cl. B81C 1/00; B81B 7/00

(52) U.S. Cl. CPC B81C 1/00269; B81B 7/0077; B81B 2201/0264; B81B 2201/0292; B81B 2201/042; B81B 2203/0361; B81B 2207/07; B81B 2207/095; B81B 2207/096; B81C 2201/019; B81C 2203/0109; B81C 2203/0118; B81C 2203/036; B81C 2203/037

(57) ABSTRACT

A manufacturing method for stacked microelectromechanical system (MEMS) devices is disclosed. The manufacturing method includes manufacturing a plurality of pair structures and eutectically bonding the plurality of pair structures. With the aid of the conductive pads and the conducting holes that electrically connect between the pair structures and among wafers of the pair structures, the purpose of integrating multiple wafers in a single chip and reducing a chip's size can be achieved.

### TECHNICAL FIELD

The present invention relates to a microelectromechanical system (MEMS) device and its fabrication method, and more particularly to a fabrication method of a MEMS device.

### BACKGROUNDS

Since the conceptualization of microelectromechanical systems (MEMS) devices in the 1970s, MEMS devices have evolved from laboratory curiosities to integral components of advanced systems, experiencing remarkable and steady growth with widespread applications in consumer devices. A MEMS device incorporates a movable micro-mechanical element, and implements its various functionalities by sensing or controlling physical movement quantities of the movable micro-mechanical element.

For sensing various physical quantities, more homogeneous or heterogeneous elements or systems are designed for faster signal transmission and smaller volume. Under the circumstances, fabricating integrated devices having high reliabilities becomes a goal that requires great efforts.

### BRIEF SUMMARY

The present disclosure discloses a fabrication method for a microelectromechanical system (MEMS) device.

In one example, the fabrication method includes providing a first wafer that includes a plurality of first conductive pads, a plurality of second conductive pads and a plurality of first conducting holes that are disposed inside the first wafer, a plurality of third conductive pads, and at least one fixed electrode that are exposed to a surface on the first wafer as well as part of the plurality of second conductive pads, where the plurality of first conducting holes are respectively connected in between the plurality of first conductive pads and the plurality of second conductive pads and in between the plurality of first conductive pads and the plurality of third conductive pads; welding a second wafer on the first wafer to form a first pair structure, the second wafer comprises a plurality of second conducting holes disposed inside the second wafer, wherein the plurality of second conducting holes are connected to the partial plurality of second conductive pads that are exposed to the first wafer, a first chamber is formed between the first wafer and the second wafer, and the plurality of third conductive pads and the fixed electrode are located inside the first chamber; forming a plurality of fourth conductive pads, a plurality of fifth conductive pads, and a first MEMS structure on the second wafer, where the plurality of fourth conductive pads are disposed on and electrically connected to the plurality of second conducting holes; providing a cap wafer that comprises a plurality of first pillars on a surface of the cap wafer; welding a third wafer on the cap wafer to form a second pair structure, where the third wafer comprises a plurality of second pillars and a plurality of germanium conductive pads on the plurality of second pillars; and eutectically bonding the first pair structure and the second pair structure, wherein the plurality of germanium conductive pads on the third wafer are physically and electrically connected with the plurality of fourth conductive pads and the plurality of fifth conductive pads on the second wafer respectively.

In one example, the fabrication method further includes thinning the first wafer and the cap wafer.

In one example, each of the second wafer and the third wafer comprises a capacitance sensor respectively.

In one example, the present disclosure discloses a MEMS stacked device fabricated using the disclosed fabrication method, and the first chamber is an airtight chamber.

In one example, the present disclosure discloses a fabrication method for a MEMS device. The disclosed fabrication method includes providing a first wafer that comprises a plurality of first conductive pads, a plurality of second conductive pads and a plurality of first conducting holes that are disposed inside the first wafer, a plurality of third conductive pads, and at least one fixed electrode that are exposed to a surface on the first wafer as well as part of the plurality of second conductive pads, where the plurality of first conducting holes are respectively connected in between the plurality of first conductive pads and the plurality of second conductive pads and in between the plurality of first conductive pads and the plurality of third conductive pads; welding a second wafer on the first wafer to form a first pair structure, the second wafer includes a plurality of second conducting holes disposed inside the second wafer, where the plurality of second conducting holes are connected to the partial plurality of second conductive pads that are exposed to the first wafer, a first chamber is formed between the first wafer and the second wafer, and the plurality of third conductive pads and the fixed electrode are located inside the first chamber; forming a plurality of fourth conductive pads, a plurality of fifth conductive pads, and a first MEMS structure on the second wafer, where the plurality of fourth conductive pads are disposed on and electrically connected to the plurality of second conducting holes; providing a cap wafer that comprises a plurality of first pillars on a surface of the cap wafer; providing a third wafer and a fourth wafer, where the third wafer comprises a plurality of second pillars and a plurality of germanium conductive pads on the plurality of second pillars, where the fourth wafer and the cap wafer are first welded together, and the fourth wafer and the third wafer are then welded together, such that a three-layer stacked structure is formed; and eutectically bonding the first pair structure and the second pair structure, where the plurality of germanium conductive pads on the third wafer are physically and electrically connected with the plurality of fourth conductive pads and the plurality of fifth conductive pads on the second wafer respectively.

Additional features and advantages of the present invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, some preferred embodiments are shown in the drawings. It should be understood, however, that the present invention is not limited to the precise arrangements and instrumentalities shown.

In the drawings:

FIGS. 1-2 illustrate a partial lateral sectional diagram of a first wafer in a fabrication process according to a first embodiment of the present invention.

FIGS. 3-4 illustrate a partial lateral sectional diagram of a first wafer in connection with a second wafer in a fabrication process according to the first embodiment of the present invention.

FIG. 5 illustrates a partial lateral sectional diagram of a cap wafer in a fabrication process according to the first embodiment of the present invention.

FIGS. 6-7 illustrate a partial lateral sectional diagram of the cap wafer in connection with a third wafer in a fabrication process according to the first embodiment of the present invention.

FIG. 8 illustrates a partial lateral sectional diagram of a stacked structure in a fabrication process according to the first embodiment of the present invention.

FIG. 9 illustrates a partial lateral sectional diagram of a stacked structure in a fabrication process according to a second embodiment of the present invention.

### DETAILED DESCRIPTION

Reference will now be made in detail to the examples of the invention, which are illustrated in the accompanying drawings. Wherever possible, the same reference numbers will be used throughout the drawings to refer to the same or like parts.

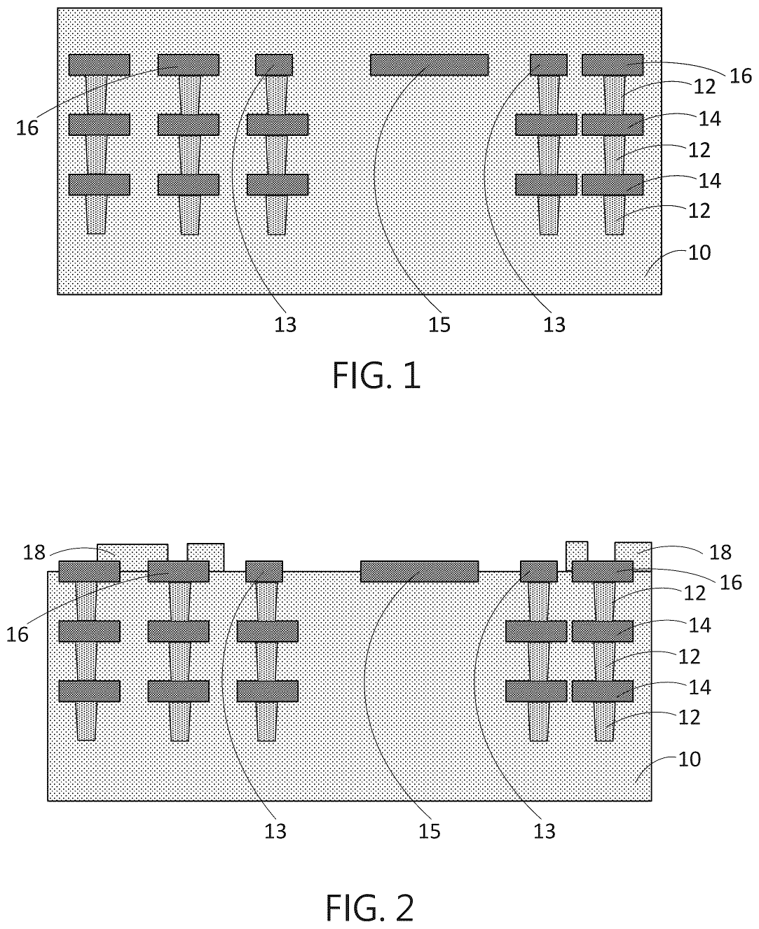

Please refer to FIGS. 1-4, which describes a fabrication method of a MEMS device shown in FIG. 1 according to one embodiment of the present invention. As shown in FIG. 1, a first wafer 10 is first provided. The first wafer 10 includes a plurality of conductive pads 14, a plurality of second conductive pads 16, a plurality of third conductive pads 13, and at least one fixed electrode 15. A first plurality of first conducting holes 12 are physically and electrically connected to and in between the first conductive pads 14 and the second conductive pads 16. A second plurality of first conducting holes 12 are physically and electrically connected to and in between the first conductive pads 14 and the third conductive pads 13. A third plurality of first conducting holes 12 are physically and electrically connected to and in between the first conductive pads 14 located at different layers. The first wafer 10 also includes analog circuits and/or digital circuits. And the first wafer 10 is ordinarily implemented using Application-Specific Integrated Circuits (ASIC)-design elements. The first wafer 10 may also be an electrode wafer. In one embodiment of the present invention, the first wafer 10 may be a wafer having appropriate mechanical rigidity, including a Complementary Metal-Oxide Semiconductor (CMOS) or a glass wafer. Even if those illustrated diagrams in the present disclosure merely illustrate a single device, however, as can be understood, there may also be multiple chips fabricated on a single wafer in other embodiments of the present invention. Therefore, embodiments of the present invention are not limited to the illustrated single device and allow fabrication of multiple devices. How to fabricate multiple chips or devices on a single wafer in a wafer fabrication process will be more detailedly described in the present disclosure. After fabricating the device, the device will be additionally processed using dicing or singulation technologies to generate single device encapsulation for succeeding application. As shown in FIG. 2, for example, the dielectric layer 18 is partially removed after forming passivation oxide layers according to a required design, such that the topmost metal layer is partially exposed to a surface of the first wafer 10, for example, exposed to sections on the third conductive pads 13, the fixed electrode 15, and/or the second conductive pads 16. In one embodiment, the metal layer is made using materials including aluminum, copper, aluminum-copper-silicon alloy, tungsten, or titanium nitride.

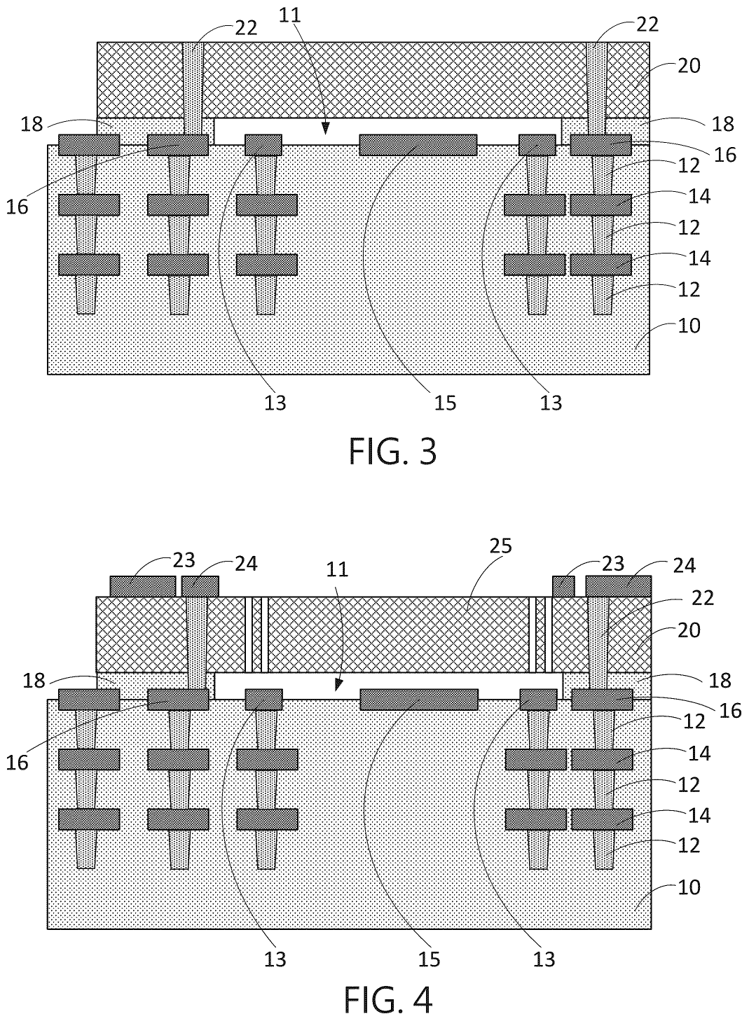

Please refer to FIG. 3, a second wafer 20 is provided and fixed on the first wafer 10 via fusion bonds. Moreover, a few via holes are formed in the second wafer 20 using laser drilling, and those formed via holes are filled with tungsten to generate a plurality of second conducting holes 22. The second conducting holes 22 are physically and electrically connected to the second conductive pads 16 that are exposed on the first wafer 10. Therefore, the second conducting holes 22 can be used as signal paths between the first wafer 10 and the second wafer 20. In addition, a first chamber 11 is formed between the first wafer 10 and the second wafer 20. The third conductive pads 13 and the fixed electrodes 15 are located within the first chamber 11, which is an airtight chamber.

Please refer to FIG. 4, a plurality of fourth conductive pads 24 and a plurality of conductive pads 23 are formed on the second wafer 20 using appropriate ways, such as physical methods or chemical depositions using aluminum and/or copper. The fourth conductive pads 24 are disposed on and electrically connected to the second conducting holes 22. Moreover, a first MEMS structure 25 is also formed on the second wafer 20 using appropriate ways. The first MEMS structure, which may be a movable structure of a capacitance sensor, corresponds to the first chamber 11, such that the second wafer 20 can be regarded as a first MEMS wafer.

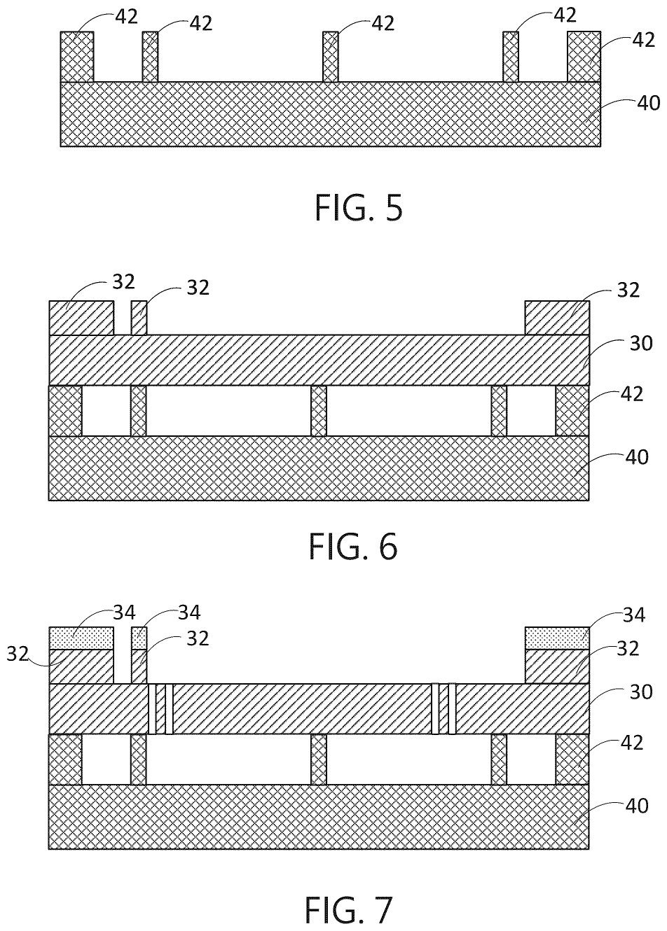

Please refer to FIG. 5, a silicon wafer is provided to fabricate a cap wafer 40. And a plurality of first pillars 42 are fabricated on the cap wafer 40 using appropriate ways, such as lithography. Please refer to FIG. 6, a third wafer 30 is fixed on the cap wafer 40 by welding to fixedly connect with the first pillars 42. A plurality of pillars 32 are also fabricated on the third wafer 30 by appropriate ways. Please refer to FIG. 7, germanium conductive pads 34 are formed on the second pillars 32 of the third wafer 30. And a second MEMS (movable) structure is fabricated on the third wafer 30, which can be regarded as a second MEMS wafer.

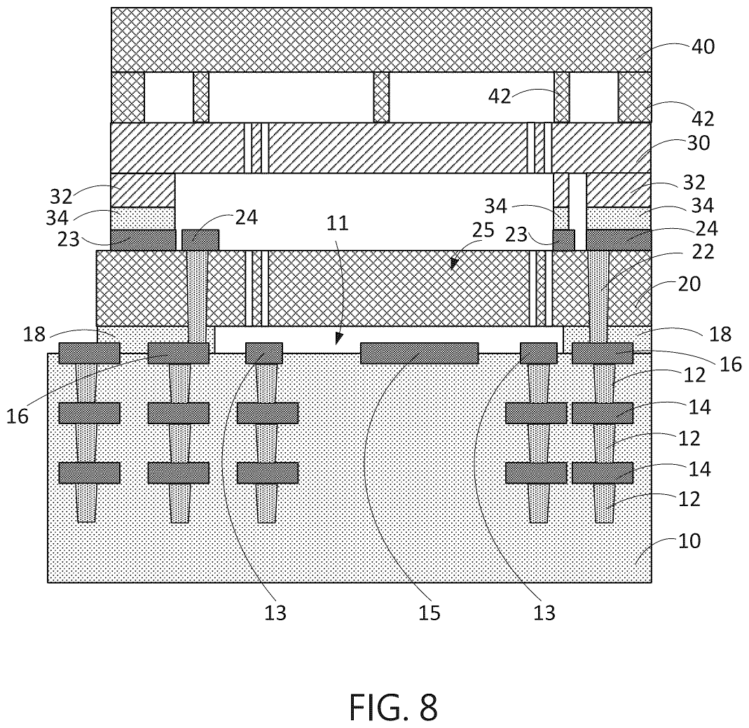

Please refer to FIG. 8, a first pair structure, which is formed via the first wafer 10 and the second wafer 20 shown in FIG. 4, and a second pair structure, which is formed via the third wafer 30 and the cap wafer 40 shown in FIG. 7, are bonded together via eutectic bonding. Specifically, the second pair structure is placed upside down. The plurality of germanium conductive pads 34 on the third wafer 30 are physically and electrically connected to the fourth conductive pads 24 and the fifth conductive pads 25 on the second wafer respectively, so as to form aluminum-germanium bonding between the germanium conductive pads 34 and each of the fourth conductive pads 24 and the fifth conductive pads 25. Last, via appropriate ways, such as laser-cutting or saw-cutting a partial structure to expose the second conductive pads 16 on the first wafer 10, where the exposed second wafer 16 can serve as wire bond pads. Depending on requirements, a back side of the first wafer 10 and a top side of the cap wafer 40, which is the side away from the third wafer 30, are respectively grounded to reduce the first wafer 10 and the cap wafer 40's required individual or integral heights, and cutting is then performed to expose the wire bond pads.

According to FIGS. 1-8, the fabrication method of the present invention includes bonding wafers in pairs to generate pair structures and then fixing the generated pair structures together via eutectic bonding. In this way, required wafers can be stacked depending on designs, where each the wafer can be fabricated as same and/or different elements. In this way, while vertically stacking homogeneous MEMS elements, signal outputs can be amplified, and die sizes can be reduced. In another aspect, while vertically stacking heterogeneous MEMS elements, elements of different applied functionalities can be integrated into a single chip. As shown in FIGS. 1-8, four silicon wafers form a stacked structure via a bonding process. A first wafer 10 (e.g. a CMOS) and a second wafer 20 are welded and bond together to generate a first pair structure. The third wafer 30 and the cap wafer 40 are also welded and bond together to generate a second pair structure. Then the second wafer 20 from the first pair structure and the third wafer 30 from the second pair structure are bond together via eutectic bonding. Also, the first wafer 10 (e.g. CMOS) and the second wafer 20 are signally connected via the second conducting holes 22. And the third wafer 30 and the second wafer 20 are signally connected via Aluminum-Germanium eutectic bonding.

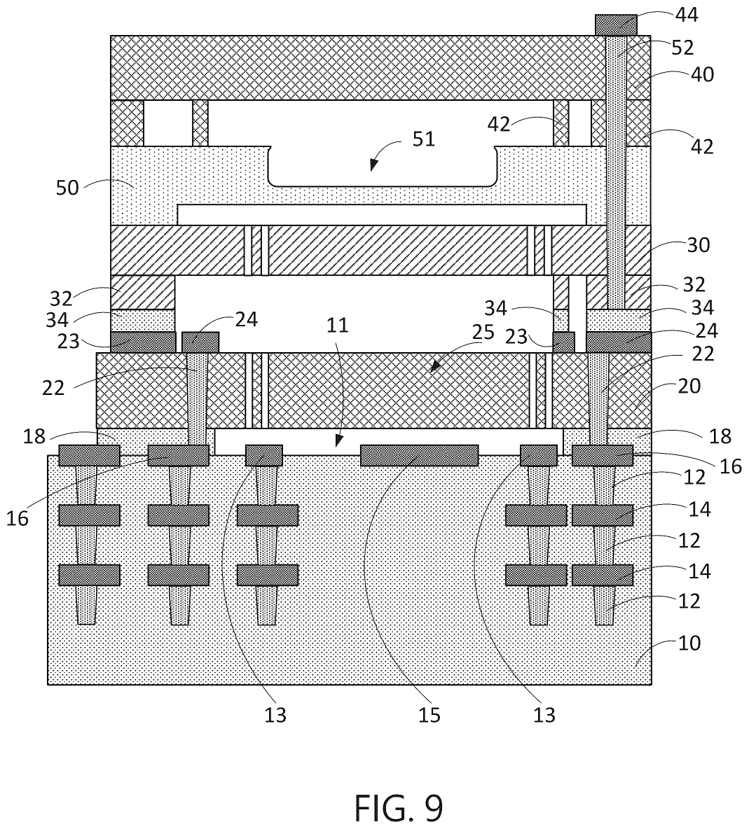

Please refer to FIG. 9, similar as FIG. 8, pair structures can be stacked with single structures by design, by forming and then stacking multiple pair structures. A fourth wafer 50 is added in FIG. 9, and can be a MEMS wafer or wafers having other functionalities. A groove 51 is disposed on a surface of the fourth wafer 50 to face toward and connect with the cap wafer 40 by welding. The connected structure of the groove 51 and the cap wafer 40 is then bonded to the third wafer 30 by welding to form a three-layer stacked structure. Last, the three-layer stacked structure is bonded to the pair structure including the first wafer 10 and the second wafer 20 via eutectic bonding. In addition, in the stacked structure shown in FIG. 9, the third conducting hole 52 penetrates through the cap wafer 40, the fourth wafer 50, and the third wafer 30 to physically and electrically connect with the germanium conductive pad 34 on the third wafer 30. Also, a sixth conductive pad 44 is formed at the cap wafer 40's top side and above the third conducting hole 52 for physically and electronically connecting with the third conducting hole 52. In this way, the whole stacked structure can be physically or electrically connected to external elements via the sixth conductive pad 44. As can be understood, the method of forming the stacked structure is not limited to the above disclosure in other embodiments of the present invention. Optionally, in other embodiments of the present invention, the third wafer 30 and the fourth wafer 50 can also be bonded together firstly, then the bonded third wafer 30 and the fourth wafer 50 can be bonded with the cap wafer 40 secondly, and the bonded third wafer 30, fourth wafer 50 and cap wafer 40 are integrated with the first pair structure that bonds the first wafer 10 and the second wafer 20. In some examples, the second wafer 20, the third wafer 30 and the fourth wafer 50 may respectively include a capacitance sensor. For example, the second wafer 20 may include a micro mirror sensor, the third wafer 30 may include a motion sensor, and the fourth wafer 50 may include a pressure sensor.

Unless the context clearly requires otherwise, throughout the description and the claims, the words “comprise,” “comprising,” and the like are to be construed in an inclusive sense (i.e., to say, in the sense of “including, but not limited to”), as opposed to an exclusive or exhaustive sense. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or” in reference to a list of two or more items, covers all of the following interpretations of the word: any of the items in the list, all of the items in the list, and any combination of the items in the list.

The above Detailed Description of examples of the invention is not intended to be exhaustive or to limit the invention to the precise form disclosed above. While specific examples for the invention are described above for illustrative purposes, various equivalent modifications are possible within the scope of the invention, as those skilled in the relevant art will recognize. While processes or blocks are presented in a given order in this application, alternative implementations may perform routines having steps performed in a different order, or employ systems having blocks in a different order. Some processes or blocks may be deleted, moved, added, subdivided, combined, and/or modified to provide alternative or sub-combinations. Also, while processes or blocks are at times shown as being performed in series, these processes or blocks may instead be performed or implemented in parallel, or may be performed at different times. Further any specific numbers noted herein are only examples. It is understood that alternative implementations may employ differing values or ranges.

While the above description describes certain examples of the invention, and describes the best mode contemplated, no matter how detailed the above appears in text, the present technology can be practiced in many ways. Details of the system may vary considerably in its specific implementation, while still being encompassed by the present technology disclosed herein. As noted above, particular terminology used when describing certain features or aspects of the present technology should not be taken to imply that the terminology is being redefined herein to be restricted to any specific characteristics, features, or aspects of the present technology with which that terminology is associated. In general, the terms used in the following claims should not be construed to limit the present technology to the specific examples disclosed in the specification, unless the above Detailed Description section explicitly defines such terms. Accordingly, the actual scope of the present technology encompasses not only the disclosed examples, but also all equivalent ways of practicing or implementing the invention under the claims.

It can be appreciated by those skilled in the art that changes could be made to the examples described above without departing from the broad inventive concept thereof. It is understood, therefore, that this invention is not limited to the particular examples disclosed, but it is intended to cover modifications within the spirit and scope of the present invention as defined by the appended claims.

Further, in describing representative examples of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

We claim:

1. A fabrication method for a microelectromechanical system (MEMS) device, comprising:
providing a first wafer that comprises a plurality of first conductive pads, a plurality of second conductive pads and a plurality of first conducting holes that are disposed inside the first wafer, a plurality of third conductive pads, and at least one fixed electrode that are exposed to a surface on the first wafer as well as part of the plurality of second conductive pads, wherein the plurality of first conducting holes are respectively connected in between the plurality of first conductive pads and the plurality of second conductive pads and in between the plurality of first conductive pads and the plurality of third conductive pads;
welding a second wafer on the first wafer to form a first pair structure, the second wafer comprises a plurality of second conducting holes disposed inside the second wafer, wherein the plurality of second conducting holes are connected to the partial plurality of second conductive pads that are exposed to the first wafer, a first chamber is formed between the first wafer and the second wafer, and the plurality of third conductive pads and the fixed electrode are located inside the first chamber;
forming a plurality of fourth conductive pads, a plurality of fifth conductive pads, and a first MEMS structure on the second wafer, wherein the plurality of fourth conductive pads are disposed on and electrically connected to the plurality of second conducting holes;
providing a cap wafer that comprises a plurality of first pillars on a surface of the cap wafer;
welding a third wafer on the cap wafer to form a second pair structure, wherein the third wafer comprises a plurality of second pillars and a plurality of germanium conductive pads on the plurality of second pillars; and
eutectically bonding the first pair structure and the second pair structure, wherein the plurality of germanium conductive pads on the third wafer are physically and electrically connected with the plurality of fourth conductive pads and the plurality of fifth conductive pads on the second wafer respectively.

2. The fabrication method of claim 1, further comprising thinning the first wafer and the cap wafer.

3. The fabrication method of claim 1, wherein each of the second wafer and the third wafer comprises a capacitance sensor respectively.

4. A MEMS stacked device fabricated using the fabrication method of claim 1, wherein the first chamber is an airtight chamber.

5. A fabrication method for a MEMS device, comprising:
providing a first wafer that comprises a plurality of first conductive pads, a plurality of second conductive pads and a plurality of first conducting holes that are disposed inside the first wafer, a plurality of third conductive pads, and at least one fixed electrode that are exposed to a surface on the first wafer as well as part of the plurality of second conductive pads, wherein the plurality of first conducting holes are respectively connected in between the plurality of first conductive pads and the plurality of second conductive pads and in between the plurality of first conductive pads and the plurality of third conductive pads;
welding a second wafer on the first wafer to form a first pair structure, the second wafer comprises a plurality of second conducting holes disposed inside the second wafer, wherein the plurality of second conducting holes are connected to the partial plurality of second conductive pads that are exposed to the first wafer, a first chamber is formed between the first wafer and the second wafer, and the plurality of third conductive pads and the fixed electrode are located inside the first chamber;
forming a plurality of fourth conductive pads, a plurality of fifth conductive pads, and a first MEMS structure on the second wafer, wherein the plurality of fourth conductive pads are disposed on and electrically connected to the plurality of second conducting holes;
providing a cap wafer that comprises a plurality of first pillars on a surface of the cap wafer;
providing a third wafer and a fourth wafer, wherein the third wafer comprises a plurality of second pillars and a plurality of germanium conductive pads on the plurality of second pillars, wherein the fourth wafer and the cap wafer are first welded together, and the fourth wafer and the third wafer are then welded together, such that a three-layer stacked structure is formed; and
eutectically bonding the first pair structure and the second pair structure, wherein the plurality of germanium conductive pads on the third wafer are physically and electrically connected with the plurality of fourth conductive pads and the plurality of fifth conductive pads on the second wafer respectively.

6. The fabrication method of claim 5, wherein the fourth wafer comprises a groove that faces the cap wafer.

7. The fabrication method of claim 5, wherein each of the second wafer, the third wafer, and the fourth wafer respectively comprises a capacitance sensor.

8. A MEMS stacked device fabricated using the fabrication method of claim 5, wherein the second wafer comprises a micro mirror sensor, the third wafer comprises a motion sensor, and the fourth wafer comprises a pressure sensor.
